(19) United States
(12) Patent Application Publication
(10) Pub. No.: US 2006/0062267 A1
(43) Pub. Date: Mar. 23, 2006

(54) Semiconductor laser array and manufacturing method for semiconductor laser array

(75) Inventor: Akira Tanaka, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/219,814

(22) Filed: Sep. 7, 2005

(30) Foreign Application Priority Data
Sep. 9, 2004 (JP) P2004-262866

(51) Int. Cl. H01S 5/00

(52) U.S. Cl. 372/43.01

(57) ABSTRACT

A semiconductor laser array includes a substrate and a first laser element provided on the substrate for emitting a first wavelength laser. The first laser element has a first multi-layer structure that includes a first active layer and a first waveguide structure. The first active layer has a first emission center. A second laser element for emitting a second wavelength laser is provided on the substrate and on the first multi-layer structure. The second laser element has a second multi-layer structure that includes a second active layer and a second wave guide structure. The second active layer has a second emission center. The second emission center is laterally and vertically spaced from the first emission center.

### CROSS REFERENCES TO RELATED APPLICATION

This application is based upon and claims the benefit of priority from the prior Japanese Patent Application No. 2004-262866, filed on Sep. 9, 2004; the entire contents of which are incorporated herein by reference.

### BACKGROUND OF THE INVENTION

In conventional DVD(digital versatile disc) players which are compatible with CD (compact disc), an optical pick up element and optical disc drive are used for the CD which use a multi-wavelength, e.g., two wavelength, semiconductor laser array (e.g., Japanese patent laid open No. 2000-11417, Japanese patent laid open No. 2001-94213).

DVD-R, DVD-RW, and DVDRAM, which are writable DVDs, are becoming more popular. Optical systems for writable DVDs are more complicated than for read only DVDs. So simplification of the multi-wavelength laser array is desirable.

The laser for writing DVDs requires high power output, e.g., 200 mW. In the laser for reading DVDs, a current block layer is the semiconductor layer which experiences optical loss (light absorption), but this optical loss is not considered a significant technical problem. However, it is important for high power output lasers that the difference in reflective index between a ridge stripe and an active layer is set to be large and light is trapped in a ridge wave guide structure.

In the above-noted Japanese patent laid open No. 2001-94213, since a second active layer is formed just above a first active layer, the waveguide structure of the active layers can be decided independently. However, in this conventional semiconductor laser array, the flatness of the laser is inferior, because the second active layer is provided just above the opening of a stripe of the first active layer. If the layers over each stripe are thickened, heat radiation from the active layer further from a mounting board of the laser array may worsen.

### SUMMARY OF THE INVENTION

One aspect of the present invention may comprise a semiconductor laser array, comprising: a substrate; a first laser element on the substrate, for emitting a first wavelength laser, having a first multi-layer structure, the first multi-layer structure having a first active layer and a first wave guide structure, the first active layer having a first emission center; and a second laser element on the substrate and on the first multi-layer structure, for emitting a second wavelength laser, having a second multi-layer structure, the second multi-layer structure having a second active layer and a second wave guide structure, the second active layer having a second emission center, the second emission center being laterally and vertically spaced from the first emission center.

Another aspect of the present invention may comprise a semiconductor laser array, comprising: a substrate; a first multi-layer structure having a first active layer and a first wave guide structure for a first laser element, the first active layer having a first emission center; a second multi-layer structure on the first multi-layer structure, having a second active layer and a second wave guide structure for a second laser element, the second active layer having a second emission center, the second emission center being laterally and vertically spaced apart from the first emission center.

A further aspect of the present invention may comprise a method for manufacturing a semiconductor laser array device, comprising: forming a first multi-layer structure for a first laser element on a substrate, the first multi-layer structure having a first active layer; forming a second multi-layer structure for a second laser element on the first multi-layer structure, the second multi-layer structure having a second active layer; exposing a part of the first multi-layer structure by removing a part of the second multi-layer structure; and forming a first wave guide structure in the first multi-layer structure and a second wave guide structure in the second multi-layer structure.

### BRIEF DESCRIPTION OF THE DRAWINGS

FIG. 1 is a cross-sectional view of a multi-wavelength semiconductor laser array consistent with a first embodiment of the present invention.

FIG. 2 is a cross-sectional view of a part of a manufacturing process of the semiconductor laser array of the first embodiment.

FIG. 3 is a cross-sectional view of a part of the manufacturing process of the semiconductor laser array of the first embodiment.

FIG. 4 is a cross-sectional view of a part of the manufacturing process of the semiconductor laser array of the first embodiment.

FIG. 5 is a cross-sectional view of a part of the manufacturing process of the semiconductor laser array of the first embodiment.

FIG. 6 is a cross-sectional view showing a semiconductor laser array mounted on a heat sink of the semiconductor laser array of the first embodiment.

FIG. 7A is a schematic view showing a position of beams on a disc emitted from a conventional semiconductor laser array;

FIG. 7B is a schematic view showing a position of beams on a disc emitted from a semiconductor laser array of the first embodiment.

FIG. 8 is a cross-sectional view of a wavelength semiconductor laser array of a first modification of the first embodiment.

FIG. 9 is an end view of a wavelength semiconductor laser array of a second modification of the first embodiment.

FIG. 10 is a cross-sectional view of a wavelength semiconductor laser array of a third modification of the first embodiment.

FIG. 11 is a cross-sectional view of a wavelength semiconductor laser array of a second embodiment consistent with the present invention.

FIG. 12 is a cross-sectional view of a part of a manufacturing process of a semiconductor laser array of the second embodiment.

FIG. 13 is a cross-sectional view of a part of the manufacturing process of the semiconductor laser array of the second embodiment.

FIG. 14 is a cross-sectional view of a part of the manufacturing process of the semiconductor laser array of the second embodiment.

### DETAILED DESCRIPTION

Embodiments of the present invention will be explained with reference to the drawings as follows.

### The First Embodiment

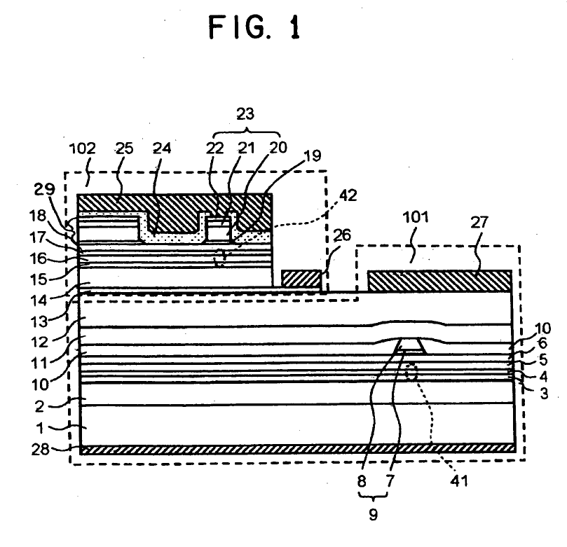

A first embodiment of the present invention will be explained hereinafter with reference to FIG. 1 to FIG. 7.

FIG. 1 is a cross-sectional view of a multi-wavelength semiconductor laser array consistent with a first embodiment of the present invention. FIG. 1 shows a cross-sectional view taken along a longitudinal direction of a resonator of the semiconductor laser array in the first embodiment. A structure of the first embodiment of the semiconductor laser array will be explained by consideration of its manufacturing process.

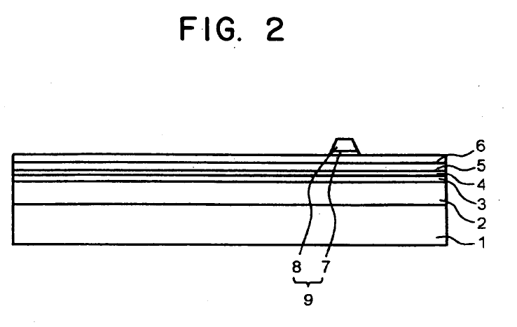

FIG. 2-FIG. 5 show cross-sectional views of respective parts of the manufacturing process of the semiconductor laser array of the first embodiment.

An n-type Al_{0.45}Ga_{0.55}As first cladding layer 2, an Al_{0.25}Ga_{0.75}As guide layer 3, an AlGaAs/AlGaAs MQW (multi-quantum well) first active layer 4, an Al_{0.25}Ga_{0.75}As guide layer 5, a p-type Al_{0.45}Ga_{0.55}As second cladding layer 6, a p-type InGaP etching stop layer 7, and a p-type Al_{0.45}Ga_{0.55}As third cladding layer 8 are grown (first crystal growing step) in this order on an n-type GaAs substrate 1 by MOVPE (Metal Organic Vapor Phase Epitaxy). A first ridge stripe 9 is formed by pattering p-type InGaP etching stop layer 7 and p-type Al_{0.45}Ga_{0.55}As third cladding layer 8. FIG. 2 shows a cross-sectional view of the manufacturing process after forming first ridge stripe 9.

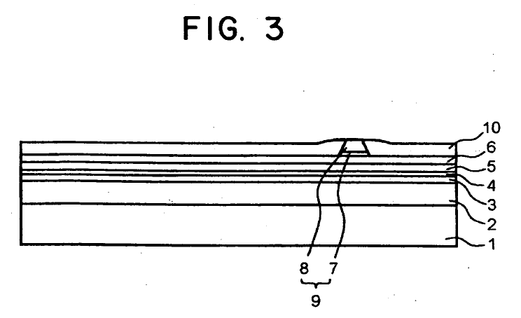

Referring to FIG. 3, on second cladding layer 6 on both sides of first ridge stripe 9, an n-type Al_{0.55}Ga_{0.45}As current block layer 10 is grown (second crystal growing step). The resulting structure of stripe 9 and layer 10 is a first wave guide structure.

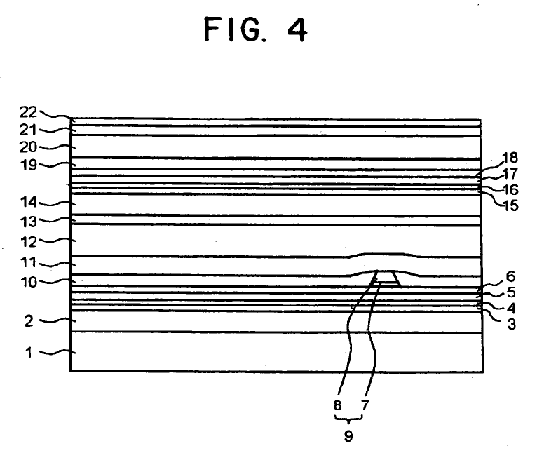

Referring to FIG. 4, a p-type Al_{0.45}Ga_{0.55}As fourth cladding layer 11, a p-type GaAs contact layer 12, an n-type GaAs contact layer 13, an n-type In_{0.5}(Ga_{0.3}Al_{0.7})_{0.5}P fifth cladding layer 14, an In_{0.5}(Ga_{0.5}Al_{0.5})_{0.5}P guide layer 15, an InGap/InGaAlP MQW second active layer 16, an In_{0.5}(Ga_{0.5}Al_{0.5})_{0.5}P guide layer 17, a p-type In_{0.5}(Ga_{0.3}Al_{0.7})_{0.5}P sixth cladding layer 18, a p-type In0.5Ga0.5P etching stop layer 19, a p-type In_{0.5}(Ga_{0.3}Al_{0.7})_{0.5}P seventh cladding 20, a p-type In_{0.5}Ga_{0.5}P interposing layer 21, and a p-type GaAs contact layer 22 are grown (third crystal growing step) in this order. FIG. 4 shows a cross-sectional view of the manufacturing process after completing the third crystal growing step.

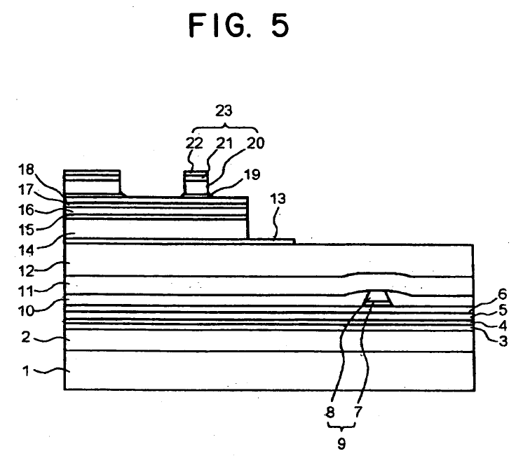

As shown in FIG. 5, a second wave guide structure is formed by forming a second ridge stripe 23. Second ridge stripe 23 is created by patterning, such as dry etching(e.g., RIE or reactive ion etching), seventh cladding layer 20, interposing layer 21, and contact layer 22.

Referring again to FIG. 1, on sixth cladding layer 18 on both sides of second ridge stripe 23, a dielectric 24 such as SiO2, a p-side electrode 25, an n-side electrode 26, a p-side electrode 27 and an n-side electrode 28 are formed. The semiconductor laser array illustrated in FIG. 1 results.

A region just above first ridge stripe 9 has undulation and is therefore not flat. It is preferable to form second ridge stripe 23 laterally spaced (in the horizontal direction in FIG. 1) from first ridge stripe 9. It is further preferable to laterally space second ridge stripe 23 no less than 10 micrometers from first ridge stripe 9. It is also preferable for second ridge stripe 23 to be laterally spaced no more than 200 micrometers from first ridge stripe 9, since a semiconductor laser array is about 200-300 micrometers, i.e., in the horizontal direction in FIG. 1. If the lateral space between first ridge stripe 9 and second ridge stripe 23 is larger, the incident angle at which one laser enters into an optical disc is inclined and an aberration may occur.

A first laser element 101 which includes first ridge stripe 9 and emits a first wavelength laser, has a first multi-layer structure. The first multi-layer structure includes layers from substrate 1 to p-type GaAs contact layer 12, p-type electrode 27 provided on p-type GaAs contact layer 12, and n-type electrode 28 provided on substrate 1.

In addition, n-type electrode 28 on substrate 1 is formed after substrate 1 is polished from ten to less than 200 micrometers in thickness. First active layer 4 of first laser element 101 has an MQW structure and its wavelength is in the 780 nanometer band (for CDs and CD-ROMs).

A second laser element 102 which includes second ridge stripe 23 and emits a second wavelength laser, has a second multi-layer structure. The second multi-layer structure includes layers from n-type GaAs contact layer 13 to p-type GaAs contact layer 22, p-type electrode 25 provided on p-type GaAs contact layer 22, and n-type electrode 26 provided on n-type GaAs contact layer 13. The active layer 16 of second laser element 102 has an MQW structure and its wavelength is in the 650 nanometer band (for DVDs).

In addition, a maximum temperature of oscillation of a 650 nanometer band laser is 90 degrees Celsius. That temperature is low compared to a 150 degrees Celsius maximum temperature of oscillation of a 780 nanometer band laser. That is, high output characteristics of the 650 nanometer band laser are limited by its maximum temperature of oscillation. So it is preferable that the 650 nanometer band laser be adapted to a real refractive index-guided self-aligned structure which is capable of reducing a loss in the current block structure.

In this first embodiment, a buried dielectric structure is adapted to second laser element 102 to enable trapping the light in the lateral direction effectively by broadening the difference of refractive index. As a result, the loss of light in the current block layer is small.

Furthermore, the transverse mode of second laser element 102, has a good characteristic, since second ridge stripe 23 is formed by dry etching which has good controllability of width. Thus, it is possible to reduce kink and output stably in a broad temperature range.

For example, a semiconductor laser element adapted to a gain guide structure, which has a high resistance region formed by implanting or a current injected region controlled by a stripe electrode, has an advantage of its easiness to flatten the surface of the laser.

On the other hand, the semiconductor laser array of the first embodiment has a real refractive index-guided self-aligned structure. So it has an advantage of adjusting a distribution of refractive index accurately and freely designing an angle of the emitting laser. Though a real refractive index-guided self-aligned structure may be inferior to a gain guide structure in the flatness of a surface of the laser, the emission centers of the first laser element 101 and second laser element 102 are laterally spaced from each other. Stacked laser elements 101 and 102 each have good emitting characteristics.

A bottom width of first ridge stripe 9 can be 0.6-1.0 micrometers, a top width of first ridge stripe 9 can be 0.4-0.8 micrometers and a height of first ridge stripe 9 can be 0.3-0.5 micrometers. A bottom width of second ridge stripe 23 can be 1.0-2.0 micrometers, a top width of second ridge stripe 23 can be 0.5-1.5 micrometers and a height of second ridge stripe 23 can be 1.0-5.0 micrometers.

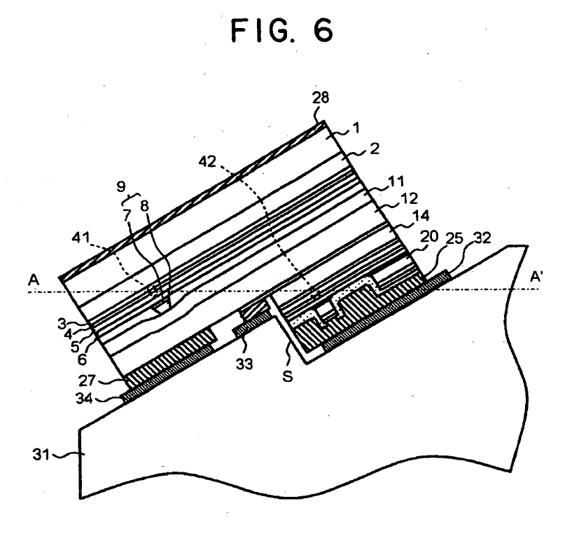

FIG. 6 is a cross-sectional view showing a semiconductor laser array of the first embodiment mounted on a heat sink. The manner by which the semiconductor laser array of a first embodiment can be mounted on a heat sink is explained by comparing with the conventional laser array shown in Japanese patent laid open No. 2000-11417. That conventional laser array which does not have a difference in level is available to mount on a heat sink with right side-up or upside-down.

On the other hand, the semiconductor laser array of the first embodiment has a differential level as shown in FIG. 1. So, it is preferable for the semiconductor laser array to be mounted upside-down on a heat sink as shown in FIG. 6. This is why the thicknesses of first laser element 101 and second laser element 102 are different. Further, to improve heat radiation from first laser element 101 and second laser element 102, it is preferable to mount the semiconductor laser array upside-down. Off course, it may be mounted right side up.

In the first embodiment, there is a difference in level between p-side electrode 25 of second laser element 102 and n-side electrode 26 of second laser element 102 (or p-side electrode 27 of first laser element 102). The thickness of the difference in level is about 2-10 micrometers, which corresponds to the thickness of layers from n-type GaAs contact layer 13 to p-type GaAs contact layer 22. So, the difference in level (step) “S” is provided in the heat sink (sub mount) as shown in FIG. 6. This may improve the efficiency of heat radiation from active layers 4 and 16.

In FIG. 6 an emission center 41 of the first laser element and an emission center 42 of the second laser element are shown. These emission centers 41 and 42 are spaced laterally and vertically from each other relative to substrate 1. The line “A-A′” shown in FIG. 6 which connected the emission centers 41 and 42 is skewed relative to substrate 1. The mount surface of heat sink 31 is skewed to keep the line “A-A′” horizontal against a reference surface of a package (not shown) for the semiconductor laser array.

In addition, there is a structure 29 spaced from second ridge stripe 23 and consisting of p-type In_{0.5}Ga_{0.5}P etching stop layer 19, p-type In_{0.5}(Ga_{0.3}Al_{0.7})_{0.5}P seventh cladding 20, p-type In_{0.5}Ga_{0.5}P interposing layer 21, and p-type GaAs contact layer 22. Structure 29 is capable of reducing stress on second ridge stripe 23 after mounting on the heat sink. In the first embodiment, the number of crystal growth steps is decreased to 3, since it is possible to grow crystals continuously after growing fourth cladding layer 11.

In the first embodiment, the wave guide structure is a real refractive index-guided self-aligned structure, and it is possible it to form a current block layer, form a stripe shaped opening, and to form a third cladding layer 8 and fourth cladding layer 11 and subsequent layers in this order.

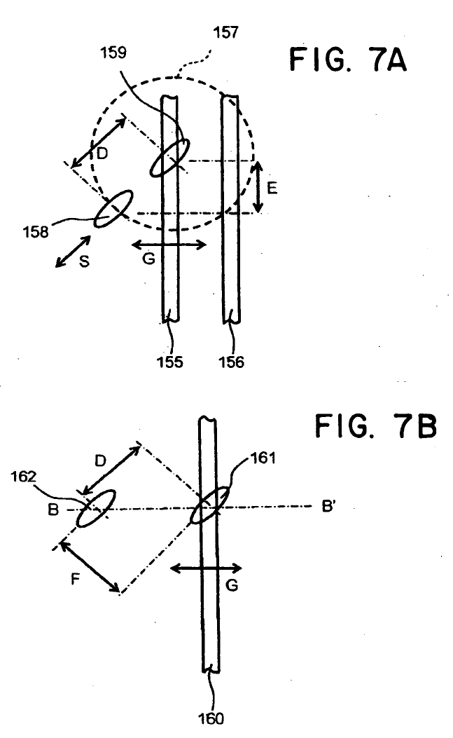

FIGS. 7A and 7B are schematic views for explaining a function of the semiconductor laser array of the first embodiment. FIG. 7A is a schematic view showing a position of beams on a track 155 on an optical disc. In a writable DVD recorder, to avoid noise of a servo signal from reflection by a next track (pit row) 156, a spread direction “S” of the beam spot 159 for DVD is angled from a tracking direction “G,” such as by 10-80 degrees. However, in the case of the conventional multi-wavelength laser, if the emission centers of the beams are positioned on a single plane, such that the spread direction of both beams coincides, the beams are irradiated by an objective lens 157 spaced by distance “D” vertically and distance “E” horizontally. Generally, however, objective lens 157 follows along the direction “G”. So, as the beam spot 158 for CD is spaced by distance “E” from the center of objective lens 157, an actuator of objective lens 157 does not adjust the lens position.

FIG. 7B is a schematic view showing a position of beams on a track 160 on an optical disc. The beam 42 for DVD (shown in FIG. 6) is focused to beam 161 spot and the beam 41 for CD (shown in FIG. 6) is focused to beam 162 spot. Between beam spots 161 and 162, the distance “D” occurs corresponding to the horizontal distance between emission centers 41 and 42 and a distance “F” occurs corresponding to the vertical distance between emission centers 41 and 42. However, by designing suitable vertical and horizontal distances between emission centers 41 and 42, the deviation along the longitudinal direction “G” of track 160 is revisable. By moving objective lens 157 toward “G”, the centers of the beams are positioned near the center of the objective lens 157. As a result, objective lens 157 is capable of following to both beams. The line “B-B′” in FIG. 7B corresponds to the line “A-A′” in FIG. 7A.

### The First Modification of the First Embodiment

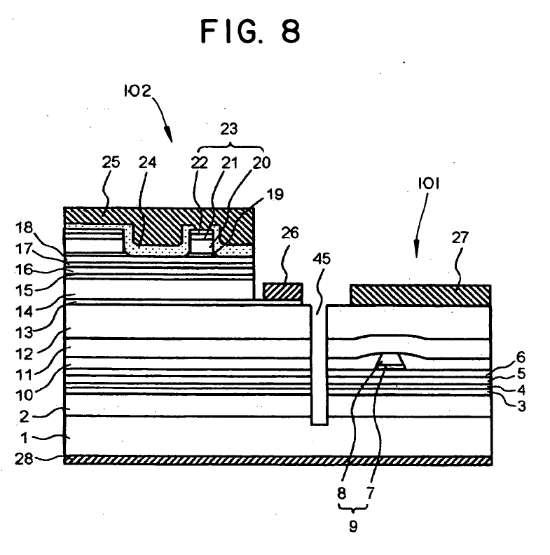

FIG. 8 is a cross-sectional view of a semiconductor laser array of a first modification of the first embodiment.

With respect to each portion of this first modification of the first embodiment, the same portions of the semiconductor laser array of the first embodiment shown in FIG. 1 to FIG. 7B are designated by the same reference numerals, and explanations of such portions are omitted.

Generally, a semiconductor laser array of the first embodiment does not drive first laser element 101 and second laser element 102, but switches them as needed by a laser driver circuit. In the structure shown in FIG. 1, first laser element 101 and second laser element 102 are electrically isolated by the pn junction between p-type GaAs contact layer 12 and n-type GaAs contact layer 13. In this modified embodiment, a trench 45 is provided between laser elements 101 and 102, as shown in FIG. 8, to avoid undesirable surge current.

### The Second Modification of the First Embodiment

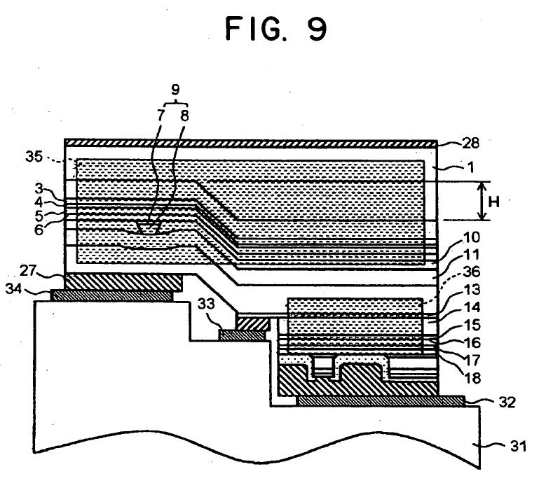

FIG. 9 is an end view of a wavelength semiconductor laser array of a second modification of the first embodiment.

With respect to each portion of the second modification of the first embodiment, the same portions of the semiconductor laser array of the first embodiment shown in FIG. 1 to FIG. 8 are designated by the same reference numerals, and explanations of such portions are omitted.

In this second modification, a difference in height “H” as shown in FIG. 9 is provided in the n-type GaAs substrate 1. On the thinner part of n-type GaAs substrate 1, first laser element 101 (for 780 nm laser) is provided and on the thicker part of n-type GaAs substrate 1, second laser element 102 (for 680 nm laser) is provided by the above mentioned manufacturing process.

According to this second modification, the vertical distance between active layers 4 and 16 is capable of being increased. So, suitable high and low first reflection layers 35 on opposite end surfaces of first laser element 101 and suitable high and low second reflection layers 36 on opposite end surfaces of second laser element 102 are formed. Further, adjusting distance “F” shown in FIG. 7 is more easily achieved by changing “H” (that is vertical distance) such that the centers of the two beams of laser elements 101 and 102 are positioned substantially in the center of the objective lens.

In general, each reflection layer 35 and 36 is formed by sputtering or ECR (electron cyclotron resonance) and made of multiple layers. For example, reflection layers 35 or 36 can be formed of alternate layers of SiO2 and SiN. This step for forming either reflection layer 35 or 36 is done efficiently, when the semiconductor laser array is in the lined bar state. In this manner, during the step of forming first reflection layer 35, second laser element 102 is covered by a mask. During the step of forming second reflection layer 36, first laser element 101 is covered by a mask. In an ordinary semiconductor laser, a low reflection layer is formed on the front edge surface and a high reflection layer is formed on the rear edge surface, and the laser emission is outputted from the front edge surface. The reflection index of each multi-layer reflection layer is changed with the wavelength of the laser. So, it is preferable to form each reflection layer independently.

The difference in height “H” of n type GaAs substrate 1 is no less than 30 micrometers in the aspect of forming reflection layers and no more than 100 micrometers in the aspect of avoiding bad crystal growing and isolation.

### The Third Modification of the First Embodiment

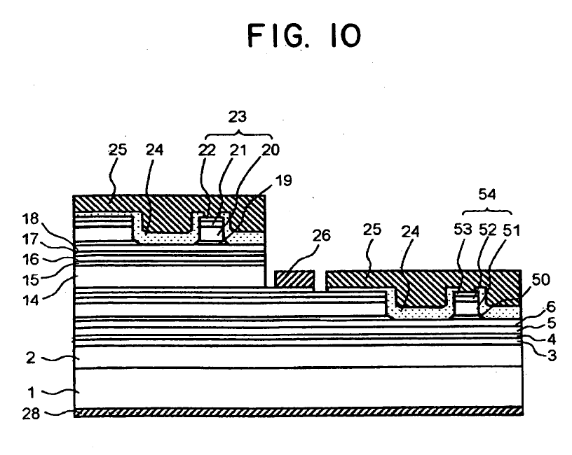

FIG. 10 is a cross-sectional view of a wavelength semiconductor laser array of a third modification of the first embodiment in the present invention.

With respect to each portion of the third modification of the first embodiment, the same portions of the semiconductor laser array of the first embodiment shown in FIG. 1 to FIG. 9 are designated by the same reference numerals, and explanations of such portions are omitted.

In this third modification, first laser element 101 has a ridge stripe structure 54 which is similar in structure to second ridge stripe 23. Ridge stripe 54 is created by patterning an n-type InGaP etching stop layer 52, a p-type AlGaAs cladding layer 51, a p-type AlGaAs cladding layer 52, and p-type GaAs contact layer 53. Dielectric layer 24 and p-side electrode 25 may be formed in the same step of forming their counterparts. Second laser element 102 is the same as in the first embodiment. In this third modification, one advantage is the number of crystal growing steps is only one.

### The Second Embodiment

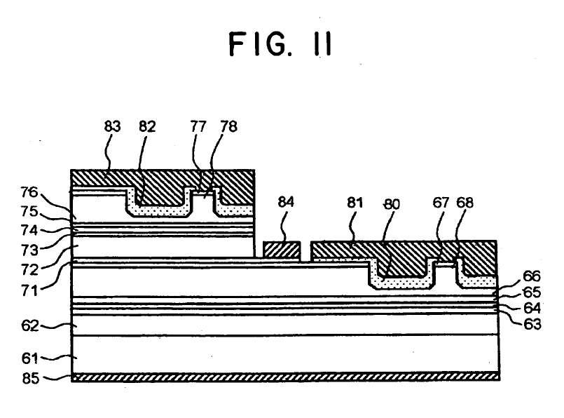

FIG. 11 is a cross-sectional view of a wavelength semiconductor laser array consistent with a second embodiment of the present invention.

With respect to each portion of the second embodiment, the same portions of the semiconductor laser array of the first embodiment shown in FIG. 1 to FIG. 10 are designated by the same reference numerals, and explanations of such portions are omitted.

The second embodiment is directed to an InGaN two wavelength semiconductor laser array. Generally, InGaN semiconductors have a wide band gap from near ultraviolet light to visible light. The wide band gap is useful for a multi-wavelength semiconductor laser array.

A structure of the second embodiment of the semiconductor laser array will be explained by consideration of its manufacturing process.

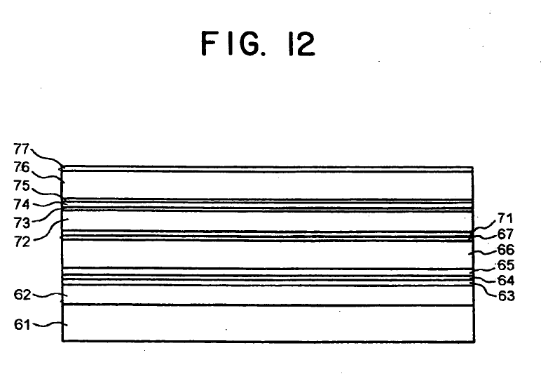

FIG. 12-FIG. 14 show cross-sectional views of parts of the manufacturing process of the semiconductor laser array of the second embodiment.

An n-type Al_{0.05}Ga_{0.95}N first cladding layer 62, an n-type GaN guide layer 63, an InGaN/InGaN MQW first active layer 64 for emitting a green laser, a p-type GaN guide layer 65, a p-type Al_{0.05}Ga_{0.95}N second cladding layer 66, a p-type GaN contact layer 67, an n-type GaN contact layer 71, an n-type Al_{0.05}Ga_{0.95}N third cladding layer 72, an n-type guide layer 73, an InGaN/InGaN MQW second active layer 74 for emitting a blue laser, a p-type GaN guide layer 75, a p-type Al_{0.05}Ga_{0.95}N fourth cladding layer 76, and a p-type GaN contact layer 77 are grown continuously on an n-type GaN substrate 61. The number of manufacturing steps of growing crystals is available to be reduced. FIG. 12 shows a cross-sectional view of the result of the manufacturing process after crystal growth steps.

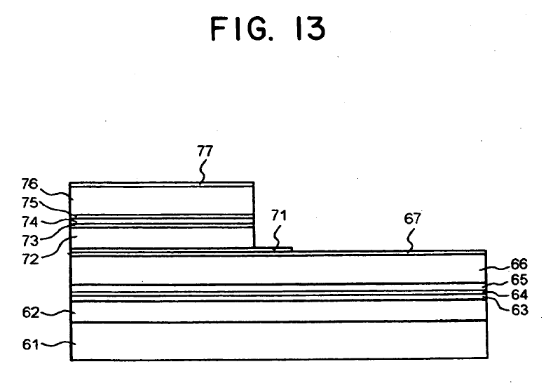

As shown in FIG. 13, a part of n-type GaN contact layer 71 is exposed by etching to create a region for forming a first ridge stripe 68, while a region for forming second ridge stripe 78 remains. As a result, a part of p-type GaN contact layer 67 is exposed by etching which is for forming first ridge stripe 68.

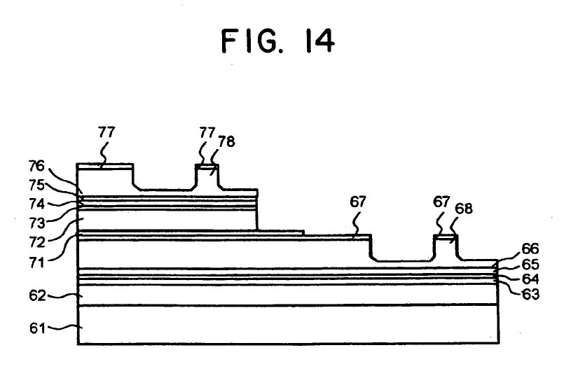

As shown in FIG. 14, first ridge stripe 68 and second ridge stripe 78 are created by etching such as by RIE.

With reference to FIG. 11, dielectrics 80 and 82 are formed on second cladding layer 66 and fourth cladding layer 76, respectively, on both sides of first ridge stripe 68 and second ridge stripe 78.

A p-side electrode 81 is formed on first ridge stripe 68. An n-side electrode 84 is formed on n-type GaN contact layer 71 and between first ridge stripe 68 and second ridge stripe 78. After n-type GaN is polished to tens to less than 200 micrometers of thickness, an n-side electrode 85 is formed on n-type GaN substrate 61. As a result, semiconductor laser array as shown FIG. 11 is manufactured.

A thickness of second cladding layer 66 and fourth cladding layer 76 can be 0.52-2.0 micrometers. A bottom width of first ridge stripe 68 and second ridge stripe 78 can be 1.0-2.0 micrometers and a top width of first ridge stripe 68 and second ridge stripe 78 can be 0.5-1.5 micrometers.

In the second embodiment, a two wavelength semiconductor laser array is manufactured by one crystal growth step.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

Semiconductor laser elements are not limited to GaAlAs, InGaAlP, and GaN lasers. Other semiconductor laser elements are available such as by using a III-V compound semiconductor, II-VI compound semiconductor, and so on.

Other embodiment of the present invention maybe possible by changing the shape, size, material, and positional relations in design by one skilled in the art.

What is claimed is:

1. A semiconductor laser array, comprising:
a substrate;
a first laser element on the substrate, for emitting a first wavelength laser, having a first multi-layer structure, the first multi-layer structure having a first active layer and a first wave guide structure, the first active layer having a first emission center; and
a second laser element on the substrate and on the first multi-layer structure, for emitting a second wavelength laser, having a second multi-layer structure, the second multi-layer structure having a second active layer and a second wave guide structure, the second active layer having a second-emission center,
the second emission center being laterally and vertically spaced from the first emission center.

2. The semiconductor laser array of claim 1, wherein at least one of the first wave guide structure and the second wave guide structure is a real refractive index-guided self-aligned structure.

3. The semiconductor laser array of claim 1, wherein at least one of the first wave guide structure and the second wave guide structure is a gain guide structure.

4. The semiconductor laser array of claim 1, wherein the first emission center and the second emission center are spaced apart no less than 2 micrometers and no more than 100 micrometers vertically and no less than 10 micrometers and no more than 200 micrometers laterally.

5. The semiconductor laser array of claim 1, further comprising a first electrode for the first laser element provided on the first emission center, a second electrode for the first laser element provided on the substrate, a first electrode for the second laser element provided on the second emission center, and a second electrode for the second laser element provided on the first multi-layer structure laterally spaced from the first emission center.

6. The semiconductor laser array of claim 5, wherein the first electrode for the first laser element and the second electrode for the second laser element are electrically insulated each other.

7. The semiconductor laser array of claim 5, wherein a height from the substrate to a top of the first electrode for the second laser element is higher than a height from the substrate to a top of the first electrode for the first laser element

8. The semiconductor laser array of claim 1, further comprising a first reflective layer on one end surface of the first laser element and a second reflective layer on one end surface of the second laser element, wherein a reflectance of the first reflective layer and a reflectance of the second reflective layer are different.

9. The semiconductor laser array of claim 7, further comprising a trench provided from a top surface of the first laser element to a direction toward the substrate.

10. A semiconductor laser array, comprising:
a substrate;
a first multi-layer structure having a first active layer and a first wave guide structure for a first laser element, the first active layer having a first emission center;
a second multi-layer structure on the first multi-layer structure, having a second active layer and a second wave guide structure for a second laser element, the second active layer having a second emission center, the second emission center being laterally and vertically spaced apart from the first emission center.

11. The semiconductor laser array of claim 10, further comprising a first ridge stripe in the first wave guide structure and on the first emission center, a second ridge stripe in the second wave guide structure and on the second emission center, wherein the first ridge stripe is laterally and vertically spaced apart from the second ridge stripe.

12. The semiconductor laser array of claim 10, wherein the first emission center and the second emission center are spaced apart no less than 2 micrometers and no more than 100 micrometers vertically and no less than 10 micrometers and no more than 200 micrometers laterally.

13. The semiconductor laser array of claim 11, further comprising a first electrode for the first laser element provided on the first ridge stripe, a second electrode for the first laser element provided on the substrate, a first electrode for the second laser element provided on the second ridge stripe, and a second electrode for the second laser element provided on the first multi-layer structure laterally spaced apart from the first ridge stripe.

14. The semiconductor laser array of claim 13, wherein the first electrode for the first laser element and the second electrode for the second laser element are-electrically insulated from each other.

15. The semiconductor laser array of claim 13, wherein a height from the substrate to a top of the first electrode for the second laser element is higher than a height from the substrate to a top of the first electrode for the first laser element

16. The semiconductor laser array of claim 10, wherein at least one of the first wave guide structure and the second wave guide structure is a real refractive index-guided self-aligned structure.

17. A method for manufacturing a semiconductor laser array device, comprising:
forming a first multi-layer structure for a first laser element on a substrate, the first multi-layer structure having a first active layer;
forming a second multi-layer structure for a second laser element on the first multi-layer structure, the second multi-layer structure having a second active layer;
exposing a part of the first multi-layer structure by removing a part of the second multi-layer structure; and
forming a first wave guide structure in the first multi-layer structure and a second wave guide structure in the second multi-layer structure.

18. The method for manufacturing semiconductor laser array device of claim 17, further comprising, forming a first ridge stripe in the first wave guide structure and forming a second ridge stripe in the second wave guide structure.

19. The method for manufacturing semiconductor laser array device of claim 18, wherein the first ridge stripe is laterally spaced from the second ridge stripe.

20. The method for manufacturing semiconductor laser array device of claim 18, further comprising forming a first electrode for the first laser element on the first ridge stripe, forming a second electrode for the first laser element on the substrate, forming a first electrode for the second laser element on the second ridge stripe, and forming a second electrode for the second laser element on the first multi-layer structure laterally spaced apart from the first ridge stripe.
